(19) United States
(12) Patent Application Publication
(10) Pub. No.: US 2022/0407517 A1
(43) Pub. Date: Dec. 22, 2022

(54) PROXIMITY AND PRESSURE DETECTION DEVICE, DETECTION LAYER AND ITEM OF EQUIPMENT EQUIPPED WITH SUCH DEVICES

(71) Applicant: FOGALE NANOTECH, Nîmes (FR)

(72) Inventors: Didier ROZIERE, Nîmes (FR); Christian NEEL, Nîmes (FR)

(21) Appl. No.: 17/756,091

(22) PCT Filed: Oct. 19, 2020
(86) PCT No.: PCT/EP2020/079304

§ 371 Date: May 17, 2022

(30) Foreign Application Priority Data
Nov. 19, 2019 (FR) 1912876

(51) Int. Cl. H03K 17/96; G01D 5/16; G01D 5/24; G01L 1/18; G01L 1/14

(52) U.S. Cl. CPC H03K 17/962; G01D 5/16; G01D 5/2405; G01L 1/18; G01L 1/14; H03K 17/964; H03K 2217/9651

(57) ABSTRACT

A device for detecting an object, with respect to a detection surface, including at least one measuring electrode, at least one emission electrode coupled to the measuring electrode by a piezoresistive layer, and measurement electronics, configured so as to bias the electrodes at the same alternating potential and perform a measurement, called capacitive measurement, of a first measured signal (Vs) relating to the capacitance (Coe), called object-electrode capacitance, seen by the at least one measuring electrode; apply a potential difference between the electrodes and measure a second signal relating to the resistance (Rie) between the electrodes. Also, a detection layer includes such a detection device as well as an item of equipment equipped with such a detection layer.

The present invention relates to a device for the detection both of proximity, i.e. the approach of and contact with an object with respect to a detection surface, and of the pressure exerted by said object on said detection surface. It also relates to a detection layer and an item of equipment equipped with such devices.

The field of the invention is the field of interfaces for capacitive detection of objects, and in particular detection interfaces for the robotics field.

### PRIOR ART

The detection interfaces equipping a surface, whether this is a surface of an electronic device of the fixed or mobile robot type, or a surface of a wall within a premises or a vehicle, make it possible to improve the interaction with surrounding objects. This interaction usually requires the ability to detect the objects present in proximity to or in contact with the surface, in particular when a robot is concerned, whether or not it is mobile. Such a detection of approach and of contact is performed by virtue of a detection surface equipped with sensors for detecting approach and contact, in particular capacitive sensors.

To complete this interaction, it seems necessary to detect, in addition to the approach and contact, the pressure exerted by an object on the detection surface. Sensors currently exist for detecting a press on a detection surface of an appliance.

However, adding such a pressure detection sensor comprising its sensor elements and its detection electronics to a detection surface already equipped with capacitive sensors of approach and contact proves expensive, bulky and complex.

An aim of the present invention is to overcome at least one of the aforementioned drawbacks.

Another aim of the present invention is to propose a detection device capable of detecting approach, contact and pressure, that is more cost-effective.

Another aim of the present invention is to propose a detection device capable of detecting approach, contact and pressure, that is less bulky.

Another aim of the present invention is to propose a detection device capable of detecting approach, contact and pressure, that is less complex.

### DISCLOSURE OF THE INVENTION

The invention makes it possible to achieve at least one of these aims by a device for detecting an object with respect to a detection surface, comprising:
at least one electrode, called measuring electrode,
at least one electrode, called emitting electrode, electrically coupled to said measuring electrode by a piezoresistive layer, and
a measurement electronics, configured to polarize at least one measuring electrode at a first alternating potential, different from a ground potential, at an operating frequency, and to perform a measurement, called capacitive measurement, of a first signal relating to the capacitance, called object-electrode capacitance, seen by said at least one measuring electrode;
   characterized in that said measurement electronics is further configured to:
apply a direct or alternating potential difference, between said at least one measuring electrode and an emitting electrode that is coupled thereto, and
perform a measurement, called resistive measurement, of a second signal relating to the resistance, called inter-electrode resistance, between said measuring electrode and said emitting electrode.

The first signal measured during the capacitive measurement step makes it possible to detect an object when the latter is approaching or in contact with the detection surface. The second signal measured during the resistive measurement step makes it possible to detect the pressure exerted by the object on the piezoresistive layer. Thus, the device according to the invention makes it possible to detect the approach, contact and pressure by a capacitive measurement and a resistive measurement, performed with one and the same measuring electrode, and by a single measurement electronics. As a result, the device according to the invention allows a detection of approach, contact and pressure, by two different types of electrical measurements, while reducing the number of sensor elements and measurement electronics used for these measurements. Thus, the device according to the invention is more cost-effective, less bulky and has a less complex architecture.

In the present application, by the term “ground potential” is meant a reference potential of the measurement electronics, which can be for example an electrical ground or a general earth potential. This ground potential can correspond to an earth potential, or to another potential whether or not connected to the earth potential.

In the present application, two alternating potentials are identical or similar at a given frequency when they each include an alternating component that is identical at this frequency, i.e. having the same amplitude and the same phase. Thus, at least one of the two potentials that are identical at said frequency can further include for example a direct component and/or an alternating component having a frequency different from said given frequency.

Similarly, two alternating potentials are different at the operating frequency when they do not have an alternating component that is identical at this operating frequency.

In the present application, the expression “proximity detection” is used to denote detecting approach and contact. This detection is performed by the capacitive measurement, and is based on the first capacitive signal.

The proximity detection makes it possible to anticipate a possible collision between a machine and an object, and in particular a human, and to modify the movements of the machine in real time by virtue for example of developed algorithms or the use of artificial intelligence, or more simply stopping this machine.

Pressure detection, also called “press detection” in the present application, is performed by the resistive measurement, and is based on the second resistive signal.

The press detection can be exploited to carry out more specific commands such as for example to effortlessly move the arm of the robot in order to guide it, in particular to carry out learning of a task.

Press detection can thus be used as a 2^{nd} type of command. It can also be used to create additional safety in order to meet safety requirements in the field of industrial robotics, for example, by performing an emergency stop function.

It is also possible to find applications in shops, museums, etc., where interactivity can be even further developed. It is thus possible to render robots even more “human”. For example, when the robot's back is approached or touched, it can turn round and react like a human, taking account of the nature of the contact.

It is also possible, when a human grasps the robot's arm, to estimate the force gripping the arm and to make the robot react as a function of this force.

In the present invention, the piezoresistive layer can be for example electrically coupled directly, resistively and/or capacitively (for example via a small coupling capacitance) with the measuring electrode and the, or each, emitting electrode that is associated therewith.

According to a particularly preferred embodiment, the device according to the invention can further comprise at least one guard electrode, disposed facing measuring and emitting electrodes, with respect to the faces thereof opposite to the detection surface.

In other words, the device according to the invention can further comprise at least one guard electrode disposed behind the measuring and emitting electrodes, seen from the side of the detection surface.

The, or each, guard electrode can be separated from the measuring and emitting electrodes by an insulating dielectric layer.

During the capacitive measurement, the guard electrode is polarized at the first alternating potential, at the operating frequency.

During the resistive measurement, the guard electrode can be polarized at the same potential as the emitting electrode, or at the same potential as the measuring electrode, or even at a different potential, at the operating frequency used for the resistive measurement.

The guard electrode can be individual to each measuring electrode.

Alternatively, or in addition, a guard electrode can be common to at least two measuring electrodes. In particular, the device according to the invention can comprise a single guard electrode for a plurality or all the measuring electrodes, thus forming a guard plane. Such a guard electrode can be formed by a layer, or a surface, that is conductive.

According to an advantageous characteristic, the piezoresistive layer can have, between at least one measuring electrode and the, or each, emitting electrode that is coupled thereto, a resistance that is of identical value to, or close to, the value of the impedance formed between said measuring electrode and the guard electrode, at the operating frequency of the capacitive measurement.

For example, the value of the resistance of the piezoresistive layer can be comprised between 1/10 and 10 times the value of the impedance formed between the measuring electrode and the guard electrode, at the operating frequency.

In particular, the value of this resistance can be greater than 1 kΩ, and preferably greater than several kΩ.

Thus, this makes it possible to limit the influence of the piezoresistive layer on the capacitive measurement, and in particular on the measurement electronics in the case where the measurement electronics comprises a charge amplifier or an amplifier of the transimpedance type.

For at least one measuring electrode, the piezoresistive layer can be disposed along the face of the emitting and measuring electrodes on the side of the detection surface.

In this case, the piezoresistive layer is located between the object to be detected and the measuring and emitting electrodes.

In this configuration, the piezoresistive layer can come into contact with the object to be detected. In this case, in order to avoid coupling or electrical contact between the object and the piezoresistive layer, provision can be made for a dielectric protection on the piezoresistive layer, for example in the form of a film of dielectric material, preferably flexible to optimize the sensitivity to pressure.

In this configuration, the piezoresistive layer can constitute, or behave as, a prolongation of the measuring electrode for the capacitive measurement, contributing to the surface area of the measuring electrode as “seen” by the object. In fact, the piezoresistive materials generally have a nominal electrical resistivity that is comprised between approximately one hundred ohms and several tens of kΩ. This type of electrical resistance can be considered as sufficiently conductive to constitute a capacitive measuring electrode. The acceptable value of this resistance depends on several parameters such as for example the excitation frequency used for the capacitive and resistive measurement, the range of capacitive measurement, the electrical characteristics of the connecting line between the sensor and the electronics, the coupling capacitances in the detection device.

Alternatively, or in addition, for at least one measuring electrode, the piezoresistive layer can be disposed along the face of the emitting and measuring electrodes on the side opposite to the detection surface.

In other words, seen from the detection surface, the piezoresistive layer can be disposed behind the measuring and emitting electrodes.

When the device according to the invention includes a guard electrode, then the piezoresistive layer can be disposed between said guard electrode and the measuring and emitting electrodes.

This embodiment allows the measuring electrode to be freed from the side of the detection surface, which makes it possible to avoid any disturbance of the capacitive measurement.

According to embodiment examples that are in no way limitative, the piezoresistive layer can comprise, or be formed by:
a foam filled with conductive particles;
a carbon foam, for example produced by pyrolysis of melamine;
a piezoelectric film, for example made from carbon-filled polymer.

The particle-filled foam can be, for example, a foam produced from flexible polymer such as polyurethane, polydimethylesiloxane (PDMS) or a polyolefin.

The conductive particles can comprise, or be, for example, metallic particles, or carbon particles in the form of carbon black, nanotubes or graphene, etc.

In the event of pressure on the foam, the bubbles present inside the foam are crushed and increase the contact surface areas between conductive particles, which contributes to reducing the resistivity, and as a result, the resistance.

According to an embodiment, a measuring electrode and at least one emitting electrode with which it is coupled can be disposed at the same level with respect to the detection surface.

The piezoresistive layer is then located on the same side as the measuring and emitting electrodes.

In this case, the thickness of the assembly formed by the measuring and emitting electrodes is reduced, which reduces the bulk of the device according to the invention.

In this embodiment, the measuring electrode and the at least one emitting electrode that is coupled thereto can be produced on one and the same conductive layer, which is easier and more cost-effective to manufacture.

Alternatively, or in addition, a measuring electrode and at least one emitting electrode with which it is coupled can be disposed one above another, with respect to the detection surface.

The piezoresistive layer is then located between the measuring and emitting electrodes.

In this case, for a given surface area, it is possible to increase the number of measuring electrodes and to improve the spatial resolution for the detection, both for the capacitive detection and for the resistive detection.

According to an advantageous characteristic that is in no way limitative, at least one measuring electrode can occupy a greater extent than that occupied by at least one emitting electrode with which it is coupled.

Thus, it is possible to have a higher spatial resolution for the resistive measurement, and thus for the pressure detection, in comparison with the capacitive measurement, and thus for the proximity detection.

In general terms, the dimensioning of the electrodes and the number thereof can be adapted to the detection environment. Depending on the size of the electrodes and the number thereof, one or more objects of large or small size can be detected simultaneously or not, as well as their displacement in 3D space and for touch in 2D.

It can be advantageous to use an emitting electrode having a surface area that is smaller than the measuring electrode. In fact, detecting approach by capacitive means does not require high spatial resolution since for an object detected at a significant distance, for example greater than the size of the measuring electrode, the field lines of the measuring electrode splay out and the spatial resolution becomes limited by principle.

In addition, detecting approach is often applied to detecting a human or an object in a machine environment in a factory, hospital, etc. and in this case, the objects in question are of significant size. On the other hand detecting touch, i.e. detecting pressure, requires better spatial resolution in order to manipulate an object, imitate a human through touch or handling.

According to an embodiment, a measuring electrode can be coupled with a single emitting electrode.

In this case, the spatial resolution of the capacitive detection will be the same as the spatial resolution of the resistive detection.

Alternatively, or in addition, a measuring electrode can be coupled with several emitting electrodes.

Thus, the spatial resolution of the resistive measurement is improved, and therefore higher, compared with that of the capacitive measurement.

In this case, the piezoresistive layer can be common to all the emitting electrodes so that a single piezoresistive layer performs the coupling between the measuring electrode and all the emitting electrodes that are coupled thereto.

Alternatively, each emitting electrode can be coupled to the measuring electrode by a separate piezoresistive layer, capable for example of being presented in the form of a disc.

According to a characteristic that is in no way limitative, a measuring electrode can be interlaced or interdigitated with at least one, in particular each, emitting electrode that is coupled thereto.

The measuring and emitting electrode or electrodes can for example be presented in the form of interdigitated combs, or any other type of geometrically interlaced structures (spirals, etc.).

This particularly advantageous characteristic makes it possible to measure, for one and the same surface, both the capacitance and the resistance, while reducing the surface area occupied by the assembly of said electrodes, and therefore while improving the spatial resolution of the capacitive detection and of the resistive detection.

Each electrode, whether it is a measuring electrode or an emitting electrode, can be produced from any conductive material.

It can in particular be produced with a metallic deposition or layer.

It can for example be produced by means of screen deposition of a layer of material based for example on silver, or any type of conductive ink.

It can also be produced with techniques of the weaving type and/or deposition on a textile support.

Alternatively, each electrode can be produced from a transparent material, such as indium tin oxide (ITO).

Generally, the measurement electronics can be digital, or analogue, or even a combination of digital components and analogue components.

The measurement electronics can comprise a polling means for sequentially polling measuring electrodes, or groups of measuring electrodes. Thus, the architecture is simplified, and the number of measurement electronics is reduced.

Such a polling means can comprise a switch connecting the measurement electronics, sequentially or in turn, to each measuring electrode, or to each group of measuring electrodes.

This switch can further be arranged so as to connect the measuring electrodes respectively either to the measurement electronics or to another potential, such as for example the first alternating potential during the capacitive measurement. According to the configurations, this other potential can be identical or substantially identical to the potential of the measuring electrodes connected to the measurement electronics, and/or correspond to the excitation potential.

Furthermore, the measurement electronics can comprise a plurality of measurement electronics, each being arranged for polling a measuring electrode, or a group of several measuring electrodes, via a polling means.

According to an embodiment example, the measurement electronics can comprise an amplifier of the transimpedance type, for example based on an operational amplifier (OA), configured for measuring a current or a load on the measuring electrode.

The OA can be arranged so that:
a first input of the OA, for example an inverting input, is connected to the measuring electrode, directly or via a polling means;
a second input, for example a non-inverting input, is connected to an oscillator supplying the first alternating potential;
the output is looped into said first input via an impedance, and in particular a capacitor and optionally a resistor.

Under these conditions, the output of the OA supplies a voltage Vₛ which relates to:
the total capacitance seen by the measuring electrode connected to the first input of the OA, for the capacitive measurement; and
the total resistance between the emitting electrode and the measuring electrode connected to the first input of the OA, for the resistive measurement, with a potential difference applied between the measuring electrode and the emitting electrode.

This configuration makes it possible to measure, during the resistive measurement, a signal that is proportional to the inverse of the resistance of the piezoresistive layer. This law (1/x) has the advantage of improving the linearity of the detection device according to the invention, during the resistive measurement, since the law of natural variation of the resistance of a piezoresistive layer is an inverse function of pressure. It is thus possible to best exploit the measurement dynamics of the device according to the invention for the resistive measurement, to efficiently detect both a light contact, for example for lifting a flexible beaker, and a strong pressure, for example for assisting a person with their movements.

The measurement electronics can be at least partially electrically referenced to the first alternating potential, at least during the capacitive measurement, and optionally during the resistive measurement. Thus, the measurement electronics do not induce unwanted capacitances visible by the measuring electrodes, which increases the precision and the reach of the capacitive detection.

According to an embodiment, the device according to the invention can comprise:
a first oscillator supplying the first alternating potential;
a second oscillator supplying a second, direct or alternating electrical potential to the measuring electrode, or to each emitting electrode, for the resistive measurement.

The second electrical potential delivered by the second oscillator can be continuous, or have the same frequency as the first alternating potential. In this case, the capacitive measurement and the resistive measurement are performed sequentially, and two measurement signals are obtained by the measurement electronics: a first measurement signal during the capacitive measurement used to deduce the first signal and a second measurement signal during the resistive measurement and used to deduce the second signal relating to the resistance.

Alternatively, the second oscillator can supply a second alternating electrical potential, having a frequency different from that of the first potential. In this case, the capacitive measurement and the resistive measurement can advantageously be performed simultaneously, and can consist of a single measurement. In other words, in this case, one and the same single measurement signal. supplied by the measurement electronics, can be used both as first measurement signal relating to the capacitance, and second measurement signal relating to the resistance. This embodiment makes it possible to reduce the number of measurements performed by the measurement electronics, since a single measurement serves both as capacitive measurement and resistive measurement. In other words, this embodiment makes it possible to improve the temporal resolution of the detection. Of course, when the second oscillator supplies a second alternating electrical potential having a frequency different from that of the first potential, it is also possible for the capacitive and resistive measurements to be performed sequentially.

According to an alternative embodiment, a single oscillator can be used to perform both the capacitive measurement and the resistive measurement.

In this case, the alternating potential supplied by this single oscillator can be used as first alternating potential for polarizing the measuring electrode and the emitting electrode or electrodes that are coupled thereto. Then, during the resistive measurement, the alternating potential supplied by this single oscillator is used to polarize one of the measuring and emitting electrodes, the other one of the electrodes being polarized at another potential, such as for example the ground potential.

The device according to the invention can further comprise a synchronous demodulation stage configured to perform a synchronous demodulation of each measurement signal, and in particular of each of the first and second measurement signals.

The demodulation stage is disposed after the measurement electronics.

The demodulation stage can be produced by means of digital physical components or analogue components (analogue multiplier, switch, etc.) and/or by calculation, for example by means of a microprocessor or an FPGA, after digitization of the measurement signal.

The demodulation stage can comprise a single demodulator for demodulating in turn the first signal relating to the capacitance, then the second signal relating to the resistance.

Alternatively, the demodulation stage can comprise two demodulators, one dedicated to demodulation of the first measurement signal and the other dedicated to demodulation of the second measurement signal. In this case, the two demodulators can be used in turn, or simultaneously.

As indicated above, it is possible for a single measurement signal supplied by the measurement electronics to be used both as first measurement signal and as second measurement signal. In this case, the first and the second demodulators perform a demodulation of this single measurement signal with different carrier waves.

The device according to the invention can further comprise a control module provided for controlling the measurement electronics, for the purpose of performing the capacitive measurement and the resistive measurement.

The control module can for example be configured to control the polarization of the measuring and emitting electrodes and to trigger a measurement.

The control module can further be configured to control the oscillator or oscillators, and the demodulation stage.

The control module can be produced in the form of a microcontroller, a processor, an electronic chip, etc. or any programmable digital component.

Advantageously, the control module can be configured to perform a step of calibration of the resistive measurement, when the capacitive measurement does not detect any object in proximity to the detection surface.

This calibration step makes it possible to determine the resistance value of the piezoresistive layer in the absence of any pressure applied to the piezoresistive layer, or a variable relating to this value. This value can then be used as threshold value to determine the presence or absence of a pressure applied to the piezoresistive layer, and/or for determining the value of the pressure applied by an object.

This calibration step can be performed as follows. A capacitive measurement can be performed by polarizing the measuring and emitting electrodes at the first alternating potential. If this capacitive measurement signals the absence of an object, then a potential difference is introduced between the measuring and emitting electrodes and a resistive measurement is performed. This resistive measurement will then supply a threshold value relative to the resistance of the piezoresistive layer at rest and in the absence of any pressure.

This calibration procedure also makes it possible to verify the correct operation of the electronics, by verifying for example that the resistance value is within an expected range of values.

Advantageously, the control module can be configured to perform a diagnostic step to verify the correct operation of the detection device according to the invention, and in particular for the capacitive detection.

In particular, this diagnostic step can be based on a measurement of the capacitance, denoted C_{eg}, between the measuring electrode and the guard electrode, in the absence of any object, when the device according to the invention comprises one or more guard electrodes. This measurement is possible in resistive measurement configurations in which the emitting and guard electrode or electrodes can be polarized at a potential different from the potential of the measuring electrode. In this case, the resistance to be measured and the capacitance C_{eg} are in parallel.

This diagnostic step can be performed as follows. In the absence of any object, verified by a capacitive measurement, a resistive measurement can be performed by applying a potential difference between the measuring electrodes on the one hand, and the emitting and guard electrodes on the other hand. The measurement signal, supplied by the measurement electronics, can then be on the one hand phase-demodulated and on the other hand quadrature-demodulated by a synchronous double detection. The result supplied by a synchronous demodulation (for example phase-demodulation) corresponds to the resistance measurement, and the result supplied by the synchronous quadrature demodulation of the former corresponds to the capacitance measurement C_{eg}. It is then possible to verify for example that this value is within an expected range. If this is not the case, this indicates a dysfunction of the device and in particular of the capacitive detection. Otherwise, the device according to the invention is operating correctly.

According to another aspect of the invention, a detection layer is proposed comprising at least one detection device according to the invention.

The detection layer can be provided to equip an object, such as a wall or a surface within a room or a vehicle, or an item of equipment of the robot or robot segment type.

The detection device of the detection layer, in particular the measuring, emitting and optionally guard electrodes, can be integrated in the detection layer, in particular within the thickness of the detection layer.

The detection electronics can also be integrated within the thickness of the detection layer. Alternatively, the detection electronics may not be integrated within the thickness of the detection layer.

The detection layer can be disposed on, or integrated in, a surface or a casing of the item of equipment.

The detection layer can alternatively be presented in the form of a trim element, such as a trim textile, independent of the item of equipment or of the wall equipped with said layer.

The detection layer can be presented in the form of a skin (or “sensory skin”) making it possible to cover all or part of the item of equipment, in particular when the item of equipment is a robot for example in humanoid form. This skin can be designed so as to have an appearance (colour, surface, feel, etc.) close to that of a human skin.

The detection layer can also be presented in the form of a tubular-shaped trim piece or element provided to be disposed, for example, around a member or a portion of a member of an item of equipment, in particular when said item of equipment is a robot and in particular a robotized arm.

The detection layer can in particular be produced in the form of a trim element such as a sheet or a cover, or form an integral part of the item of equipment, in particular when the item of equipment can also comprise an item of medical or medicalized equipment, such as a bed, a mattress, a seat or a seat cushion. In this case, the device according to the invention can be used, non-limitatively, to detect the presence of a body or of a person, their position, the pressure exerted (for example to prevent pressure sores), their movements, physiological parameters (respiration, pulse rate).

The detection layer can be flexible. For example, the detection layer can be presented in the form of a flexible skin, or of a flexible covering element.

The detection layer can be stiff. For example, the detection layer can be presented in the form of a stiff cover, or a stiff trim element.

According to another aspect of the invention, an item of equipment is proposed comprising a detection device according to the invention, or a detection layer according to the invention.

The detection layer can be disposed on, or integrated in, a surface or a casing of the item of equipment.

The detection layer can alternatively be presented in the form of a trim element, such as a trim textile, independent of said item of equipment.

The item of equipment according to the invention can be a robot or a part of a robot, mobile or fixed.

The item of equipment according to the invention can be in particular a robotized arm, a mobile robot, a wheeled or tracked vehicle, a robot of the humanoid, gynoid, android type, a robot of the real or imaginary animal type, a companion robot, etc.

The item of equipment can be a vehicle.

The item of equipment can be any type of machine, toy, etc.

The item of equipment can be a wall of a vehicle or of a room, an opening frame such as a door or window, etc.

As indicated above, the item of equipment can also comprise an item of medical or medicalized equipment, such as a bed, a mattress, a seat or a seat cushion.

### DESCRIPTION OF THE FIGURES AND EMBODIMENTS

Other advantages and characteristics will become apparent from the examination of the detailed description of an embodiment that is in no way limitative, and from the attached drawings in which

FIGS. 1-2 are diagrammatic representations, in a cross section view, of non-limitative embodiment examples of arrangements of electrodes capable of being utilized in a detection device according to the invention;

FIGS. 3-5 are diagrammatic representations, in a top view, of non-limitative embodiment examples of a combination of measuring and emitting electrodes capable of being utilized in a device according to the invention;

FIGS. 6-9 are diagrammatic representations of non-limitative embodiment examples of a detection device according to the invention;

FIG. 10 is a diagrammatic representation of a non-limitative embodiment example of an item of equipment equipped with a detection layer according to the invention; and

FIG. 11 is a diagrammatic representation of another non-limitative embodiment example of an item of equipment according to the invention.

It is well understood that the embodiments that will be described hereinafter are in no way limitative. It is possible in particular to envisage variants of the invention comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In the figures, the elements common to several figures retain the same reference.

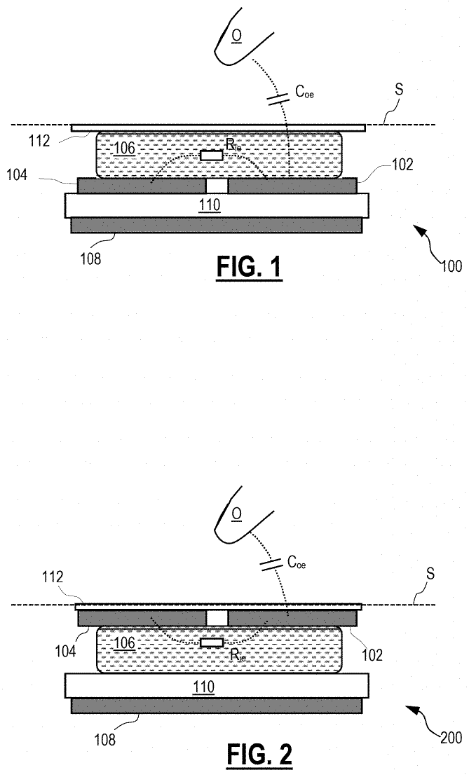

FIG. 1 is a diagrammatic representation, in a cross section view, of a non-limitative embodiment example of an arrangement of electrodes capable of being utilized in a detection device according to the invention.

The arrangement of electrodes 100, shown in FIG. 1, is used to detect on the one hand proximity, i.e. approach and contact, and on the other hand pressure exerted by an object O with respect to a detection surface S.

The arrangement 100 comprises one or more capacitive electrodes 102, called measuring electrode.

The arrangement 100 further comprises, for each measuring electrode 102, at least one capacitive electrode 104, called emitting electrode, electrically coupled with said measuring electrode 102.

The electrical coupling between the measuring electrode 102 and the emitting electrode 104 is performed by a layer of piezoresistive material 106 in electrical contact with the electrodes.

According to an optional but particularly advantageous characteristic, the arrangement of electrodes 100 can comprise a capacitive electrode 108, called guard electrode, which has the function of electrically guarding at least the measuring electrode 102. To this end, the guard electrode 108 is polarized at the same alternating potential as the measuring electrode 102, at the operating frequency.

In the example shown in FIG. 1, the guard electrode is disposed behind the measuring 102 and emitting 104 electrodes, seen from the detection surface S.

The guard electrode 108 is separated from the measuring 102 and guard 104 electrodes by a dielectric layer 110.

The arrangement of electrodes 100 is provided to be connected to a measurement electronics (not shown in FIG. 1) to polarize the measuring electrode 102, the emitting electrode 104 and the guard electrode 108, and to measure:
during a capacitive measurement, a first signal relating to a capacitance Cₒₑ, called object-electrode capacitance, seen by said at least one measuring electrode 102; and
during a resistive measurement, a second signal relating to a resistance (Rᵢₑ), called inter-electrode resistance, between said measuring electrode 102 and said emitting electrode 104.

In the example shown in FIG. 1, the measuring electrode 102 and the emitting electrode 104 are disposed at the same level and the layer of piezoresistive material 106 is disposed over these electrodes 102 and 104, on the side of the detection surface S.

In this configuration, the measuring 102 and emitting 104 electrodes can be produced in one and the same conductive layer, for example.

The layer of piezoresistive material 106 further forms a prolongation of the measuring electrode 102 for the capacitive measurement, to the extent that its surface towards the object is the one that participates in the capacitive detection of proximity of this object, i.e. in the capacitive detection of approach and contact. The apparent surface area of the measuring electrode “seen” by the object can then be greater than the surface area of the measuring electrode itself, which contributes to an increase in the reach of the capacitive detection.

In addition, in this configuration, the piezoresistive layer 106 is located on the side of the object O and forms the layer of contact with the object O. In order to avoid a coupling or an electrical contact between the object O and the piezoresistive layer 106, the latter can be covered with a dielectric thin layer 112 or a film, flexible or not, such as for example a thin layer of paint or lacquer.

The detection surface S with respect to which the approach, the contact and the pressure are detected can then be merged with the upper face of said dielectric film 112.

FIG. 2 is a diagrammatic representation of another non-limitative embodiment example of an arrangement of electrodes capable of being utilized in a detection device according to the invention.

The arrangement 200, shown in FIG. 2, comprises all the elements of the arrangement 100 in FIG. 1.

In the arrangement 200, and unlike the arrangement 100, the piezoresistive layer 106 is disposed under, or behind, the measuring 102 and emitting 104 electrodes seen from the detection surface.

In particular, la piezoresistive layer 106 is located between on the one hand the measuring 102 and emitting 104 electrodes, and on the other hand the dielectric layer 110 and the guard electrode 108. It should be noted that if the resistance of the piezoresistive layer 106 is sufficiently high, the dielectric layer 110 can be omitted.

The dielectric film 112 is disposed on the electrodes 102 and 104 to avoid an electrical coupling or contact between these electrodes and the object when the object comes into contact with these electrodes.

In this configuration, the piezoresistive layer 106 scarcely participates in the capacitive detection and therefore does not constitute an extension of the measuring electrode 102.

This configuration has the advantage that the apparent surface area of the measuring electrode “seen” by the object O is well defined as being that of the measuring electrode 102, which can increase the precision of the spatial localization of the capacitive detection.

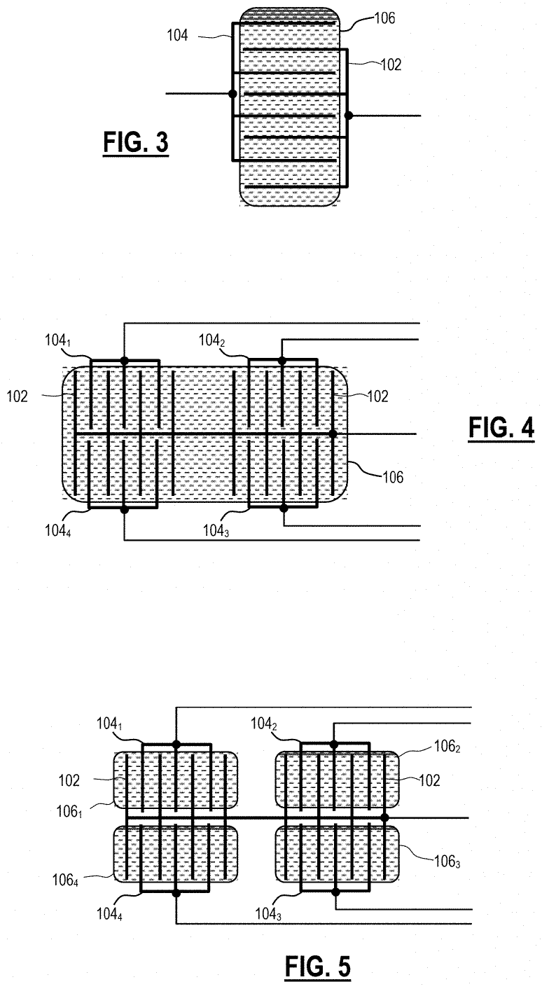

FIG. 3 is a diagrammatic representation of a non-limitative embodiment example of a combination of electrodes capable of being implemented in a detection device according to the invention.

In the example shown in FIG. 3, a single emitting electrode 104 is electrically coupled with a measuring electrode 102, via the piezoresistive layer 106.

The piezoelectric layer 106 can be located below, or above, the electrodes 102 and 104, seen from the detection surface S.

The measuring 102 and emitting 104 electrodes are interlaced or interdigitated, so as to measure over one and the same portion of surface both the object-electrode capacitance Cₒₑ and the inter-electrode resistance Rₑ. This architecture makes it possible to have one and the same spatial resolution for the capacitive measurement and for the resistive measurement.

Of course, the invention is not limited to a specific structure and any structure of electrodes, whether or not interlaced (or interdigitated), is possible.

FIG. 4 is a diagrammatic representation of another non-limitative embodiment example of a combination of electrodes capable of being implemented in a detection device according to the invention.

In the example shown in FIG. 4, a measuring electrode 102 is electrically coupled with several, in particular four, emitting electrodes 104₁-104₄ via a single piezoresistive layer 106, common to all the emitting electrodes 104₁-104₄.

The piezoresistive layer 106 can be located below, or above, the electrodes 102 and 104₁-104₄, seen from the detection surface.

Each emitting electrode 104₁-104₄ is interdigitated, or interlaced, with a part of the measuring electrode 102.

This architecture makes it possible to have a better and finer spatial resolution of the resistive measurement, with respect to the spatial resolution of the capacitive measurement.

The capacitive detection of approach and contact does not require high spatial resolution, since for an object detected at a significant distance, for example greater than the size of the electrode, the field lines of the electrode splay out and the spatial resolution becomes limited by principle. In addition, detecting approach is often applied to detecting a human or an object in a machine environment in a factory, or in a hospital, for which the objects to be detected are of significant size. On the other hand detecting pressure requires better spatial resolution in order to manipulate an object, imitate a human through touch or handling; which justifies the fact of proposing a better spatial resolution for the resistive detection in comparison with the capacitive detection.

In the example given in FIG. 4, the capacitive detection zone corresponds to the extent of the measuring electrode 102. In addition, by sequentially exciting or selecting the four emitting electrodes 104₁-104₂, it is possible to measure the pressure in sub-regions of the capacitive detection zone, with an improved spatial resolution: by a factor of 4 in the example shown.

In the example shown in FIG. 4, the piezoresistive layer is common to all the emitting electrodes 104₁-104₄.

FIG. 5 is a diagrammatic representation of another non-limitative embodiment example of a combination of electrodes capable of being implemented in a detection device according to the invention.

The example given in FIG. 5 comprises all the elements of the example given in FIG. 4, with the exception of the differences described below.

In the example shown in FIG. 5, the emitting electrodes 104₁-104₄ are not coupled to the measuring electrode 102 by a single common piezoresistive layer, as in FIG. 4.

In FIG. 5, unlike FIG. 4, each emitting electrode 104₁-104₄ is connected to the measuring electrode 102 by an individual piezoelectric layer, respectively 106₁-106₄, that is independent from the other emitting electrodes.

Each piezoresistive layer 106₁-106₄ can be presented in the form of an individual disc independent from the other piezoresistive layers 106₁-106₄.

Each piezoresistive layer 106₁-106₄ can be located below, or above, the electrodes 102 and 104₁-104₄, seen from the detection surface.

As explained above, the piezoresistive layer or layers can be produced in different ways.

In particular, in the examples illustrated, the or each piezoresistive layer can, for example, be formed by a flexible polymer foam filled with carbon particles in the form of carbon black.

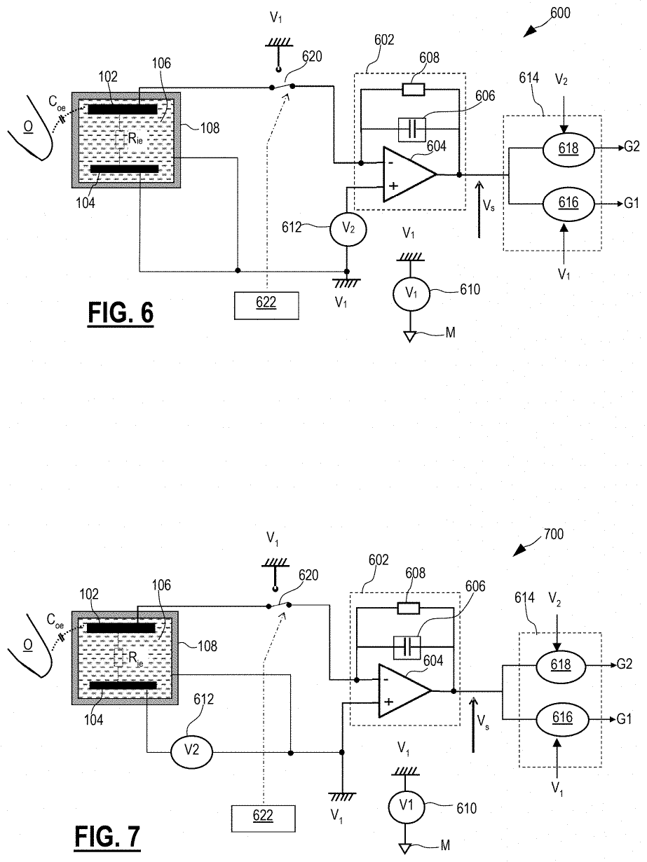

There will now be described, with reference to FIGS. 6-9, different embodiment examples of a detection device according to the invention capable of implementing any one of the arrangements 100 and 200 of electrodes in FIGS. 1-2 combined with any one of the combinations of electrodes in FIGS. 3-5.

FIG. 6 is a representation of a non-limitative embodiment example of a detection device according to the invention.

The device 600, shown in FIG. 6, comprises a multitude of measuring electrodes 102.

In FIG. 6, a single measuring electrode 102 is shown.

The device 600 comprises, for each measuring electrode 102, at least one emitting electrode 104 coupled to said measuring electrode 102 by a piezoresistive layer 106.

A guard electrode 108 can be disposed under each measuring electrode 102 and the at least one emitting electrode 104 that is coupled thereto.

The detection device 100 further comprises a measurement electronics 602 comprising an amplifier of the transimpedance type configured to measure a current or a load on the measuring electrode 102. The transimpedance amplifier 602 is formed by an operational amplifier (OA) 604, the output of which is looped into one of the inputs via a feedback capacitor 606 and a feedback resistor 608. The OA 604 supplies a voltage Vₛ at output.

The device 600 further comprises a first oscillator 610, referenced to a ground potential M, which supplies a first alternating potential V₁ (relative to the ground M) or a first alternating potential difference V₁. According to an example that is in no way limitative:

V₁=E.cos(2πf₁t).

The first alternating potential V₁ is also the guard potential for the capacitive measurement.

The device 600 further comprises a second oscillator 612, referenced to the first potential V₁, which supplies a second alternating potential V₂ (or a second alternating potential difference V₂) having a frequency different from V₁. According to an example that is in no way limitative:

V₂=E.cos(2πf₂t).

The device 600 further comprises a synchronous demodulation stage 614 for performing a synchronous demodulation of the signal Vₛ supplied by the OA 604. In the device 600, the demodulation stage 614 comprises:
a first synchronous demodulator 616 performing a synchronous demodulation of the signal Vₛ with a carrier wave identical to the first alternating potential V₁ delivered by the first oscillator 610, and
a second synchronous demodulator 618 performing a synchronous demodulation of the signal Vₛ with a carrier wave identical to the second alternating potential V₂ delivered by the second oscillator 612.

Furthermore, a switch 620 makes it possible to connect the measuring electrode 102 selectively:
either to the OA 604 when this measuring electrode 102 is used to perform a measurement: in this case, this measuring electrode 102 is called “active”;
or directly at the first potential V₁ when this measuring electrode 102 is not used to perform a measurement: in this case this measuring electrode 102 is called “passive” and constitutes a guard element for the capacitive measurement.

Optionally, the detection device 600 can further comprise a control module 622. For example, the control module 622 can be arranged to control the switch 620 for connecting the measuring electrode 102 to the OA 604 and triggering one or more measurements.

In the example shown in FIG. 6, the output of the OA 604 is looped into its inverting input “−” by the condenser 606 and the resistor 608. The inverting input of the OA 604 is connected to the measuring electrode 102. In addition, the non-inverting input “+” of the OA 604 is connected to the second oscillator 612, itself connected to the first oscillator 610, the latter being referenced to the ground potential M. The measuring electrode 104 and the guard electrode 108 are connected between the first oscillator 110 and the second oscillator 112, so that they are always polarized at the first alternating potential V₁, or guard potential.

Under these conditions, the voltage Vₛ supplied by the OA 604 comprises:
a first component, at the frequency f₁, which is a function of the coupling capacitance Cₒₑ between the measuring electrode 102 and the object O; and
a second component, at the frequency f₂, which is an inverse function of the resistance Rᵢₑ between the emitting electrode 104 and the measuring electrode 102.

The synchronous demodulation of Vₛ in the first synchronous demodulator 616 with the carrier wave V₁ supplies a variable G1 that is a function of the object-electrode capacitance Cₒₑ between the object O and the measuring electrode 102. This variable G1 makes it possible to have information on the proximity of the object O with respect to the measuring electrode 102, and therefore with respect to the detection surface S.

The synchronous demodulation of Vₛ in the second synchronous demodulator 618 with the carrier wave V₂ supplies a variable G2 that is an inverse function of the inter-electrode resistance Rᵢₑ between the measuring electrode 102 and the emitting electrode 104. This variable G2 makes it possible to have information on the pressure, or the press, applied by the object O on the piezoresistive layer 108, and therefore on the detection surface S.

In particular, as the measuring electrode 102 is connected to the inverting input of the OA 604, and the second oscillator 612 to the non-inverting input of the OA 604, the variable G2 is a function of the inverse of the resistance of the piezoresistive layer 108. This (1/x) dependency has the advantage of improving the linearity of the detection device, since the law of natural variation of the resistance of a piezoresistive layer is an inverse function of pressure. It is thus possible to best exploit the measurement dynamics of the device according to the invention for the resistive measurement, to efficiently detect a light contact, for example for lifting a flexible beaker, just as well as heavy pressure, for example for assisting a person with their movements.

In the device 600, the electronic components can be referenced via their feeds to the general ground M, in standard fashion.

In order to improve the rejection of the unwanted capacitances, the sensitive detection components such as the OA 604 and optionally the synchronous demodulation stage 614 can also be referenced to the guard potential V₁.

FIG. 7 is a representation of another non-limitative embodiment example of a detection device according to the invention.

The device 700, shown in FIG. 7, comprises all the elements of the device 600 in FIG. 6.

Unlike the device 600 in FIG. 6, in the device 700 in FIG. 7, the second oscillator 612 is disposed between the first oscillator and the emitting electrode 104.

Thus, in the device 700 this second oscillator excites the emitting electrode 104 and not the measuring electrode 102, as is the case in the device 600 in FIG. 6.

FIG. 8 is a representation of another non-limitative embodiment example of a detection device according to the invention.

The device 800 shown in FIG. 8 comprises all the elements of the device 600 in FIG. 6, with the exception of the differences described below.

In the device 800 in FIG. 8, several emitting electrodes 104₁-104_{N}, with N≥2 are coupled to the measuring electrode 102 via a single common piezoresistive layer 108, or individual piezoresistive layers.

The device 800 comprises a switch 802 that makes it possible to selectively connect each of the emitting electrodes 104₁-104_{N} in turn to the potential V₁, during the resistive measurement. Thus, it is possible to measure sequentially a variable G2₁-G2_{N} for each of the emitting electrodes 104₁-104_{N} representative of the resistance between each of the emitting electrodes 104₁-104_{N} and the measuring electrode 102.

In this example, a resistive measurement is performed sequentially, or in turn, for each of the emitting electrodes 104₁-104_{N}.

Of course, it is possible to combine the embodiment examples in FIGS. 7 and 8 and to use a second source to excite sequentially each of the emitting electrodes 104₁-104_{N}.

In the devices 600, 700 and 800, the second oscillator 612 delivers an alternating potential V₂ of frequency f₂, different from the frequency f₁ of the first alternating potential V₁. In this case, the variables G1 and G2 can be deduced from one and the same measurement signal so that the capacitive measurement and the resistive measurement are performed simultaneously. Alternatively, the variables G1 and G2 can be deduced from two measurement signals Vₛ obtained one after another, sequentially.

In addition, in the devices 600, 700 and 800, the variables G1 and G2 can be deduced simultaneously or sequentially, via two separate demodulators.

Alternatively, the variables G1 and G2 can be obtained sequentially via a single synchronous demodulator used in turn to obtain the variable G1, then the variable G2, from one and the same measurement signal Vₛ or from different measurement signals.

In the devices 600, 700 and 800, the second oscillator 612 delivers an alternating potential V₂. Alternatively, it is possible to replace this second oscillator by a direct-current electrical source delivering a direct-current voltage E.

In all cases where the capacitive measurement and the resistive measurement (or the resistive measurements) are performed sequentially, the first oscillator 610 can be guarded powered on or powered off during the, or each, resistive measurement. Similarly, the second oscillator 612 can be guarded powered on or powered off during the, or each, capacitive measurement. In this case, by powering on each of the two oscillators alternately, they can generate the same potential difference (V₁=V₂), or a potential difference at the same frequency (f₁=f₂).

In the devices 600, 700 and 800, a second oscillator 612 is used. Of course, it is possible to use only a single oscillator to perform the capacitive and resistive measurement(s). In this case, the capacitive measurement and the resistive measurement must be performed sequentially.

FIG. 9 is a representation of another non-limitative embodiment example of a detection device according to the invention.

The device 900 shown in FIG. 9 comprises all the elements of the device 600 in FIG. 6, with the exception of the differences described below.

Unlike the device 600, the device 900 comprises only the first oscillator 610 and does not comprise the second oscillator 612.

In addition, the device 900 comprises only the first demodulator 616 and does not comprise the second demodulator 618.

The device 900 comprises a contact switch 902 that selectively connects the non-inverting input of the OA 604 either at the first alternating potential V₁ or at the ground potential M.

Thus, to perform the capacitive measurement, the contact switch 902 is connected at the first alternating potential V₁. Under these conditions, the measuring electrode 102, the emitting electrode 104 and the guard electrode 108 are at the first alternating potential V₁ and a first signal Vₛ is measured. This first signal Vₛ is representative of the object-electrode capacitance Cₒₑ and is demodulated in the first demodulator 616 to obtain the variable G1, having as carrier wave the alternating potential V₁.

In order to perform the resistive measurement, the contact switch 902 is connected at the ground potential M. Under these conditions, the measuring electrode 102 is no longer polarized at the first alternating potential V₁, but at the ground potential M. The emitting electrode 104 and the guard electrode 108 are still at the first alternating potential V₁ and a second signal Vₛ is measured. This second signal Vₛ is representative of the resistance Rᵢₑ between the measuring electrodes 102 and the, or each, emitting electrode 104. This second signal Vₛ is demodulated in the first demodulator 616 to obtain the variable G2, still having as carrier wave the first alternating potential V₁.

Of course, according to an alternative, it is possible to guard the measuring electrode 102 at the first alternating potential V₁ during the resistive measurement, and to polarize the emitting electrode 104 at another potential, and in particular at the ground potential M.

In all the embodiments, it is advantageous to choose for the piezoresistive layer 106 a resistance having a value identical to, or close to, the value of the impedance formed between the measuring electrode 102 and the guard electrode 108, at the operating frequency of the capacitive measurement, i.e. the frequency f₁ in the examples described. For example, the resistance value of the piezoresistive layer 106 can be greater than 1 kΩ, and preferably greater than several kΩ.

Regardless of the embodiment described, it is possible to perform a calibration of the resistive measurement. To this end, the measuring electrode 102 and the emitting electrode 104 are polarized at the first alternating potential V₁. If this capacitive measurement signals the absence of an object, then a resistive measurement is performed. This resistive measurement will then supply a threshold value relating to the resistance of the piezoresistive layer 106 at rest, in the absence of any pressure. It also makes it possible to verify correct operation of the device.

With the devices 600, 800 and 900, it is further possible to perform a diagnosis of the capacitive measurement. This diagnosis can be performed as follows. In the absence of any object, a resistive measurement can be performed by applying the potential difference V₂ between the measuring electrodes 102 on the one hand, and the emitting 104 and guard 108 electrodes on the other hand. The measurement signal Vₛ, supplied by the measurement electronics 602, can then be on the one hand phase-demodulated and on the other hand quadrature-demodulated with the potential V₂. The result supplied by one of the demodulations (for example the phase demodulation) supplies the resistive measurement, and that supplied by the other demodulation (for example quadrature demodulation) is representative of the capacitance between the measuring electrodes 102 and the guard electrodes 108. These results can be compared to expected values, in particular to verify correct operation of the system.

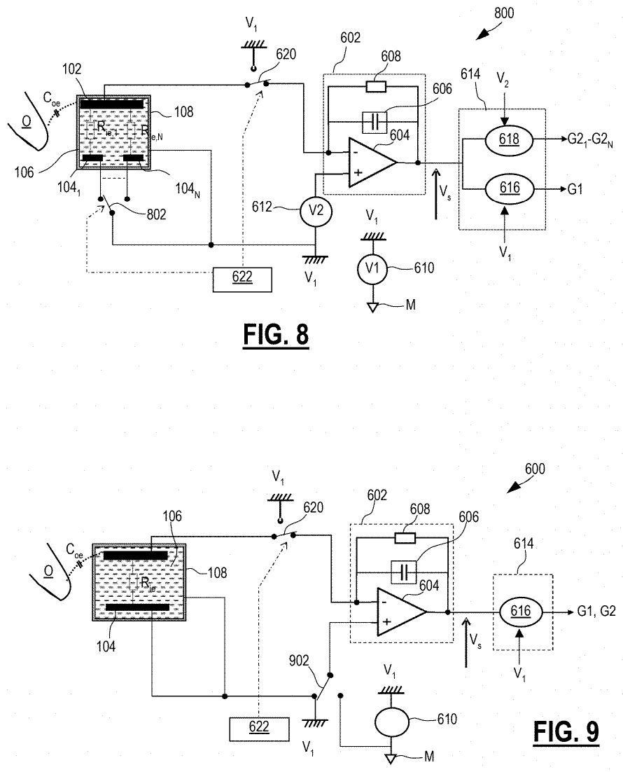

FIG. 10 is a representation of a non-limitative embodiment example of an item of equipment according to the invention.

The item of equipment 1000 in FIG. 10 is a robot, and in particular a robotized arm comprising several articulated segments, connected together by rotary articulations.

The robotized arm 1000 includes two trim elements 1002 and 1004 disposed on two segments of the robotized arm 1000.

Each trim element 1002-1004 comprises one or more detection devices according to the invention, such as for example any one of the devices 600, 700, 800 or 900 in FIGS. 6-9.

The detection electronics of different detection devices equipping the trim elements 1002 and 1004 can be separate, or partially or entirely common.

The electrodes of each detection device equipping the trim elements 1002-1004 are integrated within the thickness of said trim element 1002-1004, or disposed on one or more of the faces of said trim element 1002-1004.

The trim elements 1002-1004 are used either instead of an original trim element of the robotized arm 1000, or in addition to an original trim element.

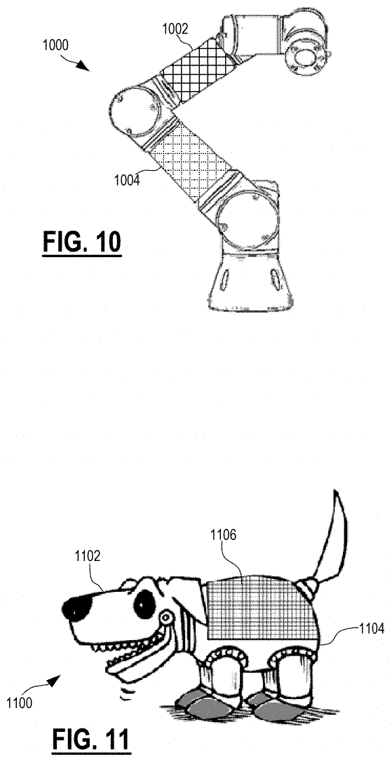

FIG. 11 is a diagrammatic representation of another non-limitative embodiment example of an item of equipment according to the invention.

The item of equipment 1100, shown in FIG. 11, is a robot in animal form.

The robot 1100 is provided with a head 1102, a body 1104 and four legs allowing said robot 1100 to move around.

The robot 1100 is equipped with a covering in the form of a skin 1106, arranged over a part of the body 1104, as illustrated, or over the entire body. The skin 1106 can be attached onto the body 1104 in such a way that it can be removed or dismantled. It can comprise a holding layer, for example a fabric sewn so as to have the desired shape.

The skin 1106 comprises one or more detection devices according to the invention, such as for example any one of the devices 600, 700, 800 or 900 in FIGS. 6-9.

Of course, the invention is not limited to the examples detailed above.

1. A device for detecting an object with respect to a detection surface, comprising:
at least one electrode, called measuring electrode;
at least one electrode, called emitting electrode, electrically coupled to said measuring electrode by a piezoresistive layer;
a measurement electronics, configured to polarize at least one measuring electrode at a first alternating potential (V₁), different from a ground potential (M), at an operating frequency, and to perform a measurement, called capacitive measurement, of a first measurement signal (Vₛ) relating to the capacitance (Cₒₑ), called object-electrode capacitance, seen by said at least one measuring electrode;
the measurement electronics is further configured to:
apply a potential difference, direct or alternating, between said at least one measuring electrode and an emitting electrode that is coupled thereto; and
perform a measurement, called resistive measurement, of a second measurement signal (Vₛ) relating to the resistance (Rᵢₑ), called inter-electrode resistance, between said measuring electrode and said emitting electrode.

2. The device according to claim 1, characterized in that it comprises at least one guard electrode, disposed facing measuring and emitting electrodes, with respect to the faces thereof opposite to the detection surface.

3. The device according to claim 2, characterized in that the piezoresistive layer has, between at least one measuring electrode and one emitting electrode that is coupled thereto, a resistance having a value identical to, or close to, the value of the impedance formed between said measuring electrode and the guard electrode, at the operating frequency of the capacitive measurement.

4. The device according to claim 1, characterized in that, for at least one measuring electrode, the piezoresistive layer is disposed along the face of the emitting and measuring electrodes on the side of the detection surface.

5. The device according to claim 1, characterized in that, for at least one measuring electrode, the piezoresistive layer is disposed along the face of the emitting and measuring electrodes on the side opposite to the detection surface.

6. The device according to claim 1, characterized in that the piezoresistive layer comprises at least one of:
a foam filled with conductive particles;
a carbon foam; and/or
a piezoresistive film.

7. The device according to claim 1, characterized in that a measuring electrode and at least one emitting electrode with which it is coupled, are disposed at the same level, with respect to the detection surface.

8. The device according to claim 1, characterized in that a measuring electrode and at least one emitting electrode with which it is coupled are disposed one above another, with respect to the detection surface.

9. The device according t claim 1, characterized in that a measuring electrode occupies a greater extent than that occupied by at least one emitting electrode with which it is coupled.

10. The device according to claim 1, characterized in that a measuring electrode is coupled with a single emitting electrode.

11. The device according to claim 1, characterized in that a measuring electrode is coupled with several emitting electrodes.

12. The device according to claim 1, characterized in that a measuring electrode is interlaced, or interdigitated, with at least one, in particular each, emitting electrode that is coupled thereto.

13. The device according to claim 1, characterized in that the measurement electronics comprises an amplifier of the transimpedance type configured to measure a current or a load on the measuring electrode.

14. The device according to claim 1, characterized in that it comprises:
a first oscillator supplying the first alternating potential (V₁);
a second oscillator supplying a second direct or alternating electrical potential (V₂) to the measuring electrode, or to each emitting electrode, for the resistive measurement.

15. The device according to claim 1, characterized in that said device further comprises a synchronous demodulation stage configured to perform a synchronous demodulation of each of the first and second signals.

16. A detection layer comprising at least one detection device according to claim 1.

17. An item of equipment including a detection device according to claim 1.

18. An item of equipment according to claim 17, characterized in that said item relates to a robot or a part of a robot, mobile or fixed.

19. An item of equipment including a detection layer according to claim 16.
